(19) United States
(12) Patent Application Publication
(10) Pub. No.: US 2026/0149447 A1
(43) Pub. Date: May 28, 2026

(54) High Power and High Performance RF Switch

(71) Applicant: Newport Fab, LLC dba Tower Semiconductor Newport Beach, Newport Beach, CA (US)

(72) Inventors: Chris Masse, Irvine, CA (US); Roda Kanawati, Irvine, CA (US); Kurt Moen, Tustin, CA (US)

(21) Appl. No.: 18/962,281

(22) Filed: Nov. 27, 2024

(51) Int. Cl. H03K 17/10

(52) U.S. Cl. CPC H03K 17/102

(57) ABSTRACT

A radio frequency (RF) switch includes an RF switch input, an RF switch output, and a stack of cascaded RF transistors. The stack of cascaded RF transistors includes a high breakdown voltage RF transistor and a low breakdown voltage RF transistor. The high breakdown voltage RF transistor is positioned closer to the RF switch input relative to the low breakdown voltage RF transistor.

### BACKGROUND

Radio frequency (RF) switches including transistors are commonly utilized in wireless communication devices (e.g., smart phones) to route signals through transmit and receive paths, for example between the device's processing circuitry and the device's antenna. RF transistors, such as field effect transistor (FET) type RF transistors, can be arranged in a stack in order to improve RF power handling of RF switches. However, as device dimensions scale down, materials used in RF switches often contribute to parasitic effects associated with RF frequencies. Particularly when RF transistors are in OFF state, these parasitic effects can result in RF switch power handling failure. Techniques to increase power handling capability generally result in RF performance tradeoffs, such as disadvantageously increasing ON-state resistance (R_{ON}). Further, these techniques tend to increase complexity by not using uniform device dimensions.

Thus, there is a need in the art for RF switches with improved RF performance and power handling, and uniform device dimensions.

### SUMMARY

The present disclosure is directed a high power and high performance RF switch, substantially as shown in and/or described in connection with at least one of the figures, and as set forth in the claims.

### BRIEF DESCRIPTION OF THE DRAWINGS

FIG. 1 illustrates a portion of a radio frequency (RF) switch employing RF transistors and corresponding exemplary voltage amplitude graphs.

FIG. 2 illustrates a portion of an RF switch employing RF transistors and corresponding exemplary voltage amplitude graphs according to one implementation of the present application.

FIG. 3 illustrates a portion of an RF transceiver employing RF switches according to one implementation of the present application.

FIG. 4 illustrates a portion of an RF transceiver employing RF switches according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

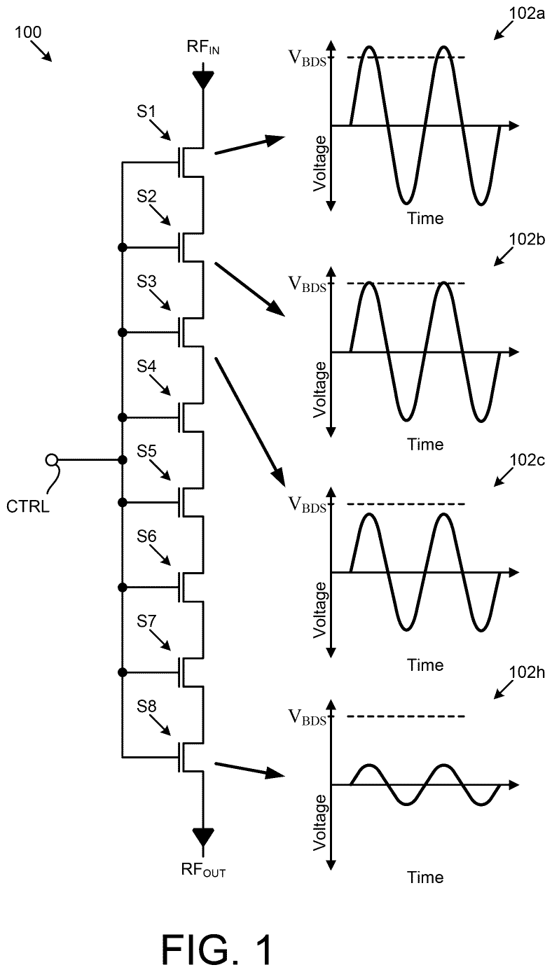

FIG. 1 illustrates a portion of a radio frequency (RF) switch employing RF transistors and corresponding exemplary voltage amplitude graphs. As shown in FIG. 1, RF switch 100 includes RF switch input RF_{IN}, RF switch output RF_{OUT}, control node CTRL, and a stack of cascaded RF transistors S1, S2, S3, S4, S5, S6, S7, and S8 (collectively referred to as S1 through S8). Cascaded RF transistors S1 through S8 are coupled between an RF switch input RF_{IN} and an RF output RF_{OUT}. A drain of transistor S1 is coupled to RF switch input RF_{IN}. A source of each of transistors S1 through S7 is coupled to a drain of a subsequent transistor. A source of transistor S8 is coupled to RF output RF_{OUT}. Gates of cascaded RF transistors S1 through S8 are coupled to a control node CTRL for switching RF switch 100 between ON and OFF states. In the ON state, an RF signal input at RF switch input RF_{IN} and will generally pass through RF switch 100 to RF output RF_{OUT}. In the OFF state, an RF signal input at RF switch input RF_{IN} and will generally be blocked. Control node CTRL can be coupled to a microcontroller and/or pulse generator (not shown in FIG. 1).

Each of cascaded RF transistors S1 through S8 is standard or general-purpose RF transistor designed to balance a variety of performance characteristics, such as insertion loss, power handling capability, etc. Cascaded RF transistors S1 through S8 are identical, excepting normal process variation. Each of cascaded RF transistors S1 through S8 has a standard breakdown voltage V_{BDS}. By stacking cascaded RF transistors S1 through S8 as shown in Figure, the overall OFF state power handling capability of RF switch 100 is increased. In the present implementation, RF switch 100 includes eight cascaded RF transistors S1 through S8. In various implementations, RF switch 100 can include more or fewer cascaded RF transistors than shown.

FIG. 1 illustrates exemplary voltage amplitude graphs 102a, 102b, 102c, and 102h. Voltage graphs 102a, 102b, 102c, and 102h illustrate exemplary voltage amplitudes versus time for respective cascaded RF transistors S1, S1, S3, and S8 when switch 100 is in an OFF state. Voltage graph 102a represents the voltage measured across the drain and source of cascaded RF transistor S1. Likewise, voltage graph 102b represents the voltage measured across the drain and source of cascaded RF transistor S2, voltage graph 102c represents the voltage measured across the drain and source of cascaded RF transistor S3, and voltage graph 102h represents the voltage measured across the drain and source of cascaded RF transistor S8. Voltage graphs 102a, 102b, 102c, and 102h illustrate sinusoidal RF voltages across corresponding RF transistors in response to a sinusoidal RF voltage provided by RF switch input RF_{IN} when switch 100 is in an OFF state.

As shown by graphs 102a, 102b, 102c, and 102h, RF voltage distribution in RF switch 100 is iteratively less across each cascaded RF transistor in the stack. In one example, the RF voltage at RF switch input RF_{IN} may be approximately twenty volts (20 V). Rather than this input being distributed evenly across cascaded RF transistors S1 through S8 as 2.5 V per transistor, the voltage distribution is iteratively less across each cascaded RF transistor in the stack. This uneven voltage distribution can be attributed to parasitic effects. Continuing the above example where the RF voltage at RF switch input RF_{IN} is 20 V, voltage across cascaded RF transistor S1 may be approximately 4.6 V, voltage across cascaded RF transistor S2 may be approximately 4 V, voltage across cascaded RF transistor S3 may be approximately 3.4 V, and voltage across cascaded RF transistor S8 may be approximately 0.4 V.

Significantly, if the standard breakdown voltage V_{BDS} of identical cascaded RF transistors S1 through S8 is not greater than the largest voltage across any cascaded RF transistor S1 through S8, RF switch 100 can experience failure. As shown by voltage graphs 102a, 102b, 102c, and 102h, in the present implementation, two cascaded RF transistors S1 and S2 positioned closest to RF switch input RF_{IN} would have voltages across them that exceed their standard breakdown voltage V_{BDS}. Meanwhile, the voltages across remaining cascaded RF transistors S3 through S8 are less than their standard breakdown V_{BDS}. Continuing the above example where the voltages across cascaded RF transistors S1 and S2 would be approximately 4.6 V and 4 V respectively, if standard breakdown voltage V_{BDS} is 3.9 V, then RF switch 100 would experience failure.

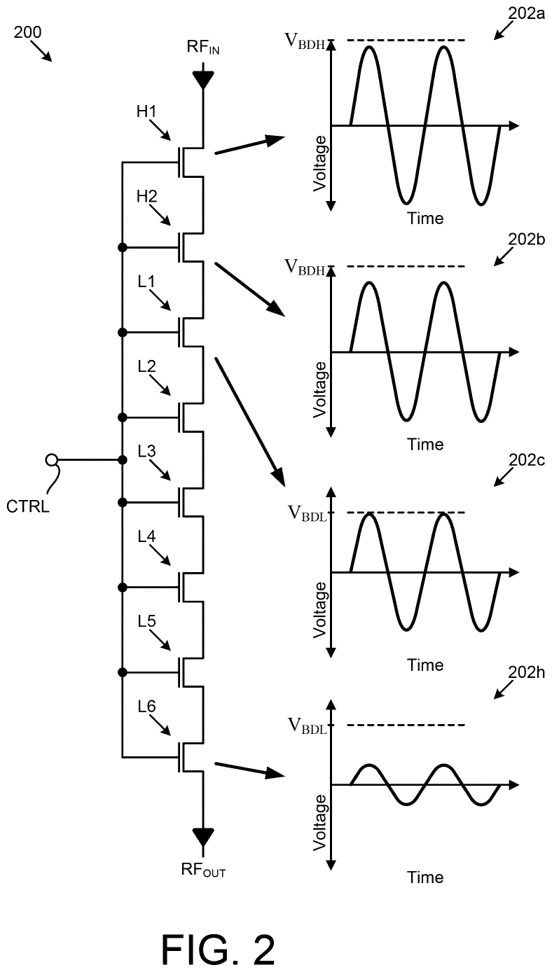

FIG. 2 illustrates a portion of an RF switch employing RF transistors and corresponding exemplary voltage amplitude graphs according to one implementation of the present application. Like RF switch 100 in FIG. 1, RF switch 200 in FIG. 2 includes a stack of cascaded RF transistors. In contrast to RF switch 100 in FIG. 1 which included standard cascaded RF transistors, RF switch 200 in FIG. 2 includes high breakdown voltage RF transistors H1 and H2 and low breakdown voltage RF transistors L1, L2, L3, L4, L5, and L6.

High breakdown voltage RF transistors H1 and H2 are positioned closer to RF switch input RF_{IN} relative to said low breakdown voltage RF transistors L1 through L6. A drain of high breakdown voltage RF transistor H1 is coupled to RF switch input RF_{IN}. A source of high breakdown voltage RF transistor H1 is coupled to a drain of high breakdown voltage RF transistor H2. A source of high breakdown voltage RF transistor H2 is coupled to a drain of low breakdown voltage RF transistor L1. A source of each of low breakdown voltage RF transistors L1 through L5 is coupled to a drain of a subsequent low breakdown voltage RF transistor. A source of low breakdown voltage RF transistor L6 is coupled to RF output RF_{OUT}.

Each of the cascaded RF transistors in RF switch 200 is either high breakdown voltage or low breakdown voltage. High breakdown voltage RF transistors H1 and H2 are identical to each other, excepting normal process variation, and have high breakdown voltage V_{BDH}. Similarly, low breakdown voltage RF transistors L1 through L6 are identical to each other, excepting normal process variation, and have low breakdown voltage V_{BDL}. High breakdown voltage V_{BDH} is greater than low breakdown voltage V_{BDL}. In one implementation, low breakdown voltage V_{BDL} is approximately three and a half volts (3.5 V) or less, and high breakdown voltage V_{BDH} is approximately five volts (5 V) or greater.

High breakdown voltage RF transistors H1 and H2 can be substantially similar to low breakdown voltage RF transistors L1 through L6, excepting design features needed to increase/decrease their breakdown voltages. In one implementation, high breakdown voltage RF transistors H1 and H2 have substantially the same channel dimensions as low breakdown voltage RF transistors L1 through L6. In one implementation, high breakdown voltage RF transistors H1 and H2 have substantially the same active device area as low breakdown voltage RF transistors L1 through L6.

High breakdown voltage RF transistors H1 and H2 can be configured to have higher breakdown voltages than low breakdown voltage RF transistors L1 through L6 using any technique known in the art. As examples, high breakdown voltage RF transistors H1 and H2 can be configured to have higher breakdown voltage V_{BDH} using techniques described in U.S. patent application Ser. No. 17/847,006, filed on Jun. 22, 2022, titled “SOI Structures with Carbon in Body Regions for Improved RF-SOI Switches,” and U.S. patent application Ser. No. 18/382,892, filed on Oct. 23, 2023, titled “Radio Frequency (RF) Semiconductor-On-Insulator (SOI) Device with Improved Power Handling.” The disclosures and contents of the above-identified patent applications are hereby incorporated fully by reference into the present application.

In the present implementation, RF switch 200 includes eight cascaded RF transistors, two of which are high breakdown voltage RF transistors. In various implementations, RF switch 200 can include more or fewer cascaded RF transistors and/or can include a different ratio of high breakdown voltage RF transistors to low breakdown voltage RF transistors than shown in FIG. 2. For example, RF switch 200 could include a third high breakdown voltage RF transistor (e.g., H3) in place of low breakdown voltage RF transistor L1. Generally, given the nature of the iteratively decreasing voltage distribution described above, less than half of the cascaded RF transistors of a given stack may be high breakdown voltage RF transistors. In various implementations, for stacks containing twenty or fewer cascaded RF transistors, four or fewer may be high breakdown voltage RF transistors.

FIG. 2 illustrates exemplary voltage amplitude graphs 202a, 202b, 202c, and 202h. Voltage graphs 202a, 202b, 202c, and 202h illustrate exemplary voltage amplitudes versus time for respective cascaded RF transistors H1, H2, L1, and L6 when switch 200 is in an OFF state. Voltage graph 202a represents the voltage measured across the drain and source of high breakdown voltage RF transistor H1. Likewise, voltage graph 202b represents the voltage measured across the drain and source of high breakdown voltage RF transistor H2, voltage graph 202c represents the voltage measured across the drain and source of low breakdown voltage RF transistor L1, and voltage graph 202h represents the voltage measured across the drain and source of low breakdown voltage RF transistor L6. Voltage graphs 202a, 202b, 202c, and 202h illustrate sinusoidal RF voltages across corresponding RF transistors in response to a sinusoidal RF voltage provided by RF switch input RF_{IN} when switch 200 is in an OFF state.

As shown by graphs 202a, 202b, 202c, and 202h, RF voltage distribution in RF switch 200 is iteratively less across each cascaded RF transistor in the stack. Significantly, as shown by graphs 202a and 202b, high breakdown voltage V_{BDH} is greater than the largest voltage across high breakdown voltage RF transistors H1 and H2, so RF switch 200 does not experience failure. Similarly, as shown by graphs 202c and 202h, low breakdown voltage V_{BDL}, although lower than high breakdown voltage V_{BDH}, is still greater than the largest voltage across low breakdown voltage RF transistors L1 through L6, so RF switch 200 does not experience failure. Continuing the above example where the voltages across high breakdown voltage RF transistor H1 and low breakdown voltage RF transistor L1 would be approximately 4.6 V and 3.4 V respectively, if high breakdown voltage V_{BDH} is approximately 5 V and low breakdown voltage V_{BDL} is approximately 3.5 V, then RF switch 100 would not experience failure.

RF switches using mixed high breakdown voltage and low breakdown voltage transistors according to the present application, such as RF switch 200 in FIG. 2, advantageously avoid OFF state switch failure for a given input voltage without modifying channel dimensions or device area, without adding additional transistors to the stack, and without increasing the breakdown voltages of every transistor in the stack, which would significantly increasing insertion loss. Compared to RF switch 100 in FIG. 1, RF switch 200 in FIG. 2 can utilize the same physical layout while significantly increasing power handling capability without significantly increasing insertion loss. In one example, RF switch 200 may have approximately ten percent (+10%) greater power handling capability at the cost of approximately one percent (+1%) greater insertion loss.

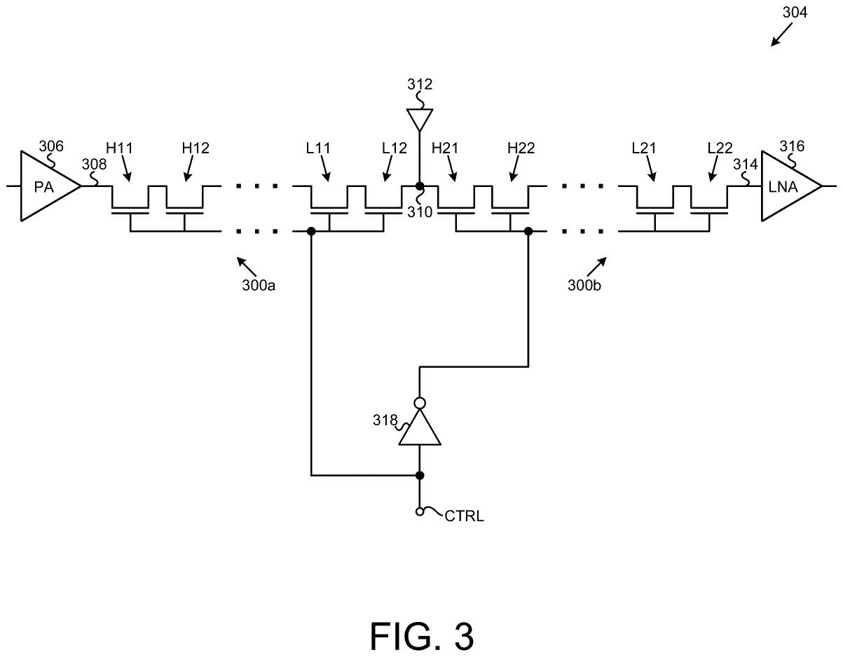

FIG. 3 illustrates a portion of an RF transceiver employing RF switches according to one implementation of the present application. As shown in FIG. 3, RF transceiver 304 includes power amplifier (PA) 306, transmit input 308, transmit series RF switch 300a, transmit output or receive input 310, antenna 312, receive series RF switch 300b, receive output 314, low noise amplifier (LNA) 316, inverter 318, and control node CTRL.

Transmit input 308 is coupled to PA 306 and represents an RF signal to be transmitted by RF transceiver 304. Transmit series RF switch 300a is situated between PA 306 and antenna 312. Transmit series RF switch 300a includes a transmit series stack of cascaded RF transistors, including transmit series high breakdown voltage RF transistors H11 and H12 as well as transmit series low breakdown voltage RF transistors L11 and L12. Transmit series high breakdown voltage RF transistors H11 and H12 are positioned closer to transmit input 308 relative to transmit series low breakdown voltage RF transistors L11 and L12. Transmit output or receive input 310 is coupled to antenna 312. In one implementation, antenna 312 can include an antenna array.

Receive series RF switch 300b is situated between antenna 312 and LNA 316. Receive series RF switch 300b includes a receive series stack of cascaded RF transistors, including receive series high breakdown voltage RF transistors H21 and H22 as well as receive series low breakdown voltage RF transistors L21 and L22. Receive series high breakdown voltage RF transistors H21 and H22 are positioned closer to receive input 310 relative to receive series low breakdown voltage RF transistors L21 and L22. Receive output 314 is coupled to LNA 316 and represents an RF signal to be received by RF transceiver 304.

Gates of cascaded RF transistors of transmit series RF switch 300a are coupled to control node CTRL. Control node CTRL is coupled to the input of inverter 318. The output of inverter 318 is coupled to gates of cascaded RF transistors of receive series RF switch 300b. Control node CTRL switches transmit series RF switch 300a and receive series RF switch 300b between ON and OFF states. Transmit series RF switch 300a, receive series RF switch 300b, inverter 318, and control node CTRL together function as a single pole double throw (SPDT) RF switch to switch RF transceiver 304 between transmit and receive modes.

In the transmit mode, control node CTRL and transmit series RF switch 300a are ON and receive series RF switch 300b is OFF. PA 306 is coupled to antenna 312 by transmit series RF switch 300a. LNA 316 is isolated from antenna 312 across receive series RF switch 300b. Conversely, in the receive mode, control node CTRL and transmit series RF switch 300a are OFF and receive series RF switch 300b is ON. PA 306 is isolated from antenna 312 by transmit series RF switch 300a. LNA 316 is coupled to antenna 312 across receive series RF switch 300b.

Transmit series RF switch 300a and receive series RF switch 300b in FIG. 3 generally correspond to RF switch 200 in FIG. 2 and may have any implementations or advantages described above. As an example, transmit series high breakdown voltage RF transistors H11 and H12 have the same breakdown voltage as each other, and transmit series low breakdown voltage RF transistors L11 and L12 have the same breakdown voltage as each other. Likewise, receive series high breakdown voltage RF transistors H21 and H22 have the same breakdown voltage as each other, and receive series low breakdown voltage RF transistors L21 and L22 have the same breakdown voltage as each other. As another example, transmit series high breakdown voltage RF transistors H11 and H12 as well as transmit series low breakdown voltage RF transistors L11 and L12 can have the same channel dimensions. Likewise, receive series high breakdown voltage RF transistors H21 and H22 as well as receive series low breakdown voltage RF transistors L21 and L22 can have the same channel dimensions. In one implementation, transmit series RF switch 300a and receive series RF switch 300b are identically designed. In various implementations, transmit series RF switch 300a and receive series RF switch 300b can include more or fewer cascaded RF transistors than shown.

Because RF transceiver 304 employs RF switches using mixed high breakdown voltage and low breakdown voltage transistors according to the present application, power handling capability of RF transceiver 304 is significantly increased without significantly increasing insertion loss. It is noted that the design of RF transceiver 304 is merely exemplary. RF switch 200 in FIG. 2 may be utilized in other RF devices or circuits.

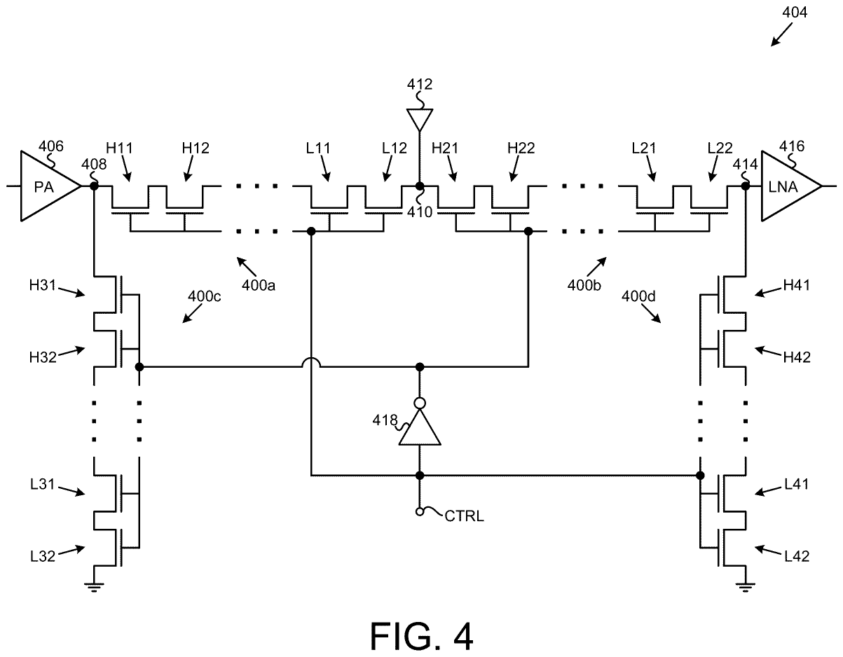

FIG. 4 illustrates a portion of an RF transceiver employing RF switches according to one implementation of the present application. As shown in FIG. 4, RF transceiver 404 includes PA 406, transmit input 408, transmit series RF switch 400a, transmit output or receive input 410, antenna 412, receive series RF switch 400b, receive output 414, LNA 416, inverter 418, control node CTRL, transmit shunt RF switch 400c, and receive shunt RF switch 400d.

Except for differences noted below, PA 406, transmit input 408, transmit series RF switch 400a, transmit output or receive input 410, antenna 412, receive series RF switch 400b, receive output 414, LNA 416, inverter 418, and control node CTRL in FIG. 4 generally correspond to PA 306, transmit input 308, transmit series RF switch 300a, transmit output or receive input 310, antenna 312, receive series RF switch 300b, receive output 314, LNA 316, inverter 318, and control node CTRL in FIG. 3 and may have any implementations or advantages described above.

As shown in FIG. 4, transmit shunt RF switch 400c is situated between PA 406 and ground. Transmit shunt RF switch 400c includes a transmit shunt stack of cascaded RF transistors, including transmit shunt high breakdown voltage RF transistors H31 and H32 as well as transmit shunt low breakdown voltage RF transistors L31 and L32. Transmit shunt high breakdown voltage RF transistors H31 and H32 are positioned closer to transmit input 408 relative to transmit shunt low breakdown voltage RF transistors L31 and L32.

Receive shunt RF switch 400d is situated between LNA 416 and ground. Receive shunt RF switch 400d includes a receive shunt stack of cascaded RF transistors, including receive shunt high breakdown voltage RF transistors H41 and H42 as well as receive shunt low breakdown voltage RF transistors L41 and L42. Receive shunt high breakdown voltage RF transistors H41 and H42 are positioned closer to receive output 414 relative to receive shunt low breakdown voltage RF transistors L41 and L42.

Gates of cascaded RF transistors of transmit shunt RF switch 400c are coupled to the output of inverter 418 is control node CTRL. Gates of cascaded RF transistors of receive shunt RF switch 400d are coupled to control node CTRL and the input of inverter 418. In the transmit mode, control node CTRL, transmit series RF switch 400a, and receive shunt RF switch 400d are ON, and receive series RF switch 400b and transmit shunt RF switch 400c are OFF. PA 406 is coupled to antenna 412 by transmit series RF switch 400a and isolated from ground across transmit shunt RF switch 400c. LNA 416 is isolated from antenna 412 across receive series RF switch 400b and coupled to ground by receive shunt RF switch 400d. Conversely, in the receive mode, control node CTRL, transmit series RF switch 400a, and receive shunt RF switch 400d are OFF, and receive series RF switch 400b and transmit shunt RF switch 400c are ON. PA 406 is isolated from antenna 412 across transmit series RF switch 400a and coupled to ground by transmit shunt RF switch 400c. LNA 416 is coupled to antenna 412 by receive series RF switch 400b and isolated from ground across receive shunt RF switch 400d.

Transmit shunt RF switch 400c and receive shunt RF switch 400d in FIG. 4 generally correspond to RF switch 200 in FIG. 2 and may have any implementations or advantages described above. As an example, transmit shunt high breakdown voltage RF transistors H31 and H32 have the same breakdown voltage as each other, and transmit shunt low breakdown voltage RF transistors L31 and L32 have the same breakdown voltage as each other. Likewise, receive shunt high breakdown voltage RF transistors H41 and H42 have the same breakdown voltage as each other, and receive shunt low breakdown voltage RF transistors L41 and L42 have the same breakdown voltage as each other. As another example, transmit shunt high breakdown voltage RF transistors H31 and H32 as well as transmit shunt low breakdown voltage RF transistors L31 and L32 can have the same channel dimensions. Likewise, receive shunt high breakdown voltage RF transistors H41 and H42 as well as receive shunt low breakdown voltage RF transistors L41 and L42 can have the same channel dimensions. In one implementation, transmit series RF switch 400a, receive series RF switch 400b, transmit shunt RF switch 400c, and receive shunt RF switch 400d are identically designed. In various implementations, transmit shunt RF switch 400cand receive shunt RF switch 400d can include more or fewer cascaded RF transistors than shown.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. An RF switch comprising:
an RF switch input;
an RF switch output;
a stack of cascaded RF transistors including a high breakdown voltage RF transistor and a low breakdown voltage RF transistor;
said high breakdown voltage RF transistor being positioned closer to said RF switch input relative to said low breakdown voltage RF transistor.

2. The RF switch of claim 1, wherein said high breakdown voltage RF transistor and said low breakdown voltage RF transistor have substantially the same channel dimensions.

3. The RF switch of claim 1, wherein said low breakdown voltage RF transistor has a breakdown voltage of less than approximately three and a half volts (3.5 V) and said high breakdown voltage RF transistor has a breakdown voltage of greater than approximately five volts (5 V).

4. The RF circuit of claim 1, wherein each of said cascaded RF transistors of said stack has approximately the same breakdown voltage as either said high breakdown voltage RF transistor or said low breakdown voltage RF transistor.

5. A radio frequency (RF) transceiver comprising:
a transmit series RF switch comprising a transmit series stack of cascaded RF transistors, said transmit series stack of cascaded RF transistors including a transmit series high breakdown voltage RF transistor and a transmit series low breakdown voltage RF transistor, said transmit series high breakdown voltage RF transistor being positioned closer to a transmit input relative to said transmit series low breakdown voltage RF transistor;
a receive series RF switch comprising a receive series stack of cascaded RF transistors, said receive series stack of cascaded RF transistors including a receive series high breakdown voltage RF transistor and a receive series low breakdown voltage RF transistor, said receive series high breakdown voltage RF transistor being positioned closer to a receive input relative to said receive series low breakdown voltage RF transistor.

6. The RF transceiver of claim 5, wherein said transmit series RF switch is situated between a power amplifier (PA) and an antenna, and said receive series RF switch is situated between said antenna and a low noise amplifier (LNA).

7. The RF transceiver of claim 6, wherein said transmit input is coupled to said PA, and said receive input is coupled to said antenna.

8. The RF transceiver of claim 5, further comprising:
a transmit shunt RF switch comprising a transmit shunt stack of cascaded RF transistors, said transmit shunt stack of cascaded RF transistors including a transmit shunt high breakdown voltage RF transistor and a transmit shunt low breakdown voltage RF transistor, said transmit shunt high breakdown voltage RF transistor being positioned closer to said transmit input relative to said transmit shunt low breakdown voltage RF transistor.

9. The RF transceiver of claim 5, further comprising:
a receive shunt RF switch comprising a receive shunt stack of cascaded RF transistors, said receive shunt stack of cascaded RF transistors including a receive shunt high breakdown voltage RF transistor and a receive shunt low breakdown voltage RF transistor, said receive shunt high breakdown voltage RF transistor being positioned closer to a receive output relative to said receive shunt low breakdown voltage RF transistor.

10. The RF transceiver of claim 5, further comprising:
a transmit shunt RF switch comprising a transmit shunt stack of cascaded RF transistors, said transmit shunt stack of cascaded RF transistors including a transmit shunt high breakdown voltage RF transistor and a transmit shunt low breakdown voltage RF transistor, said transmit shunt high breakdown voltage RF transistor being positioned closer to said transmit input relative to said transmit shunt low breakdown voltage RF transistor;
a receive shunt RF switch comprising a receive shunt stack of cascaded RF transistors, said receive shunt stack of cascaded RF transistors including a receive shunt high breakdown voltage RF transistor and a receive shunt low breakdown voltage RF transistor, said receive shunt high breakdown voltage RF transistor being positioned closer to a receive output relative to said receive shunt low breakdown voltage RF transistor.

11. The RF transceiver of claim 10, wherein:
said transmit shunt high breakdown voltage RF transistor and said transmit shunt low breakdown voltage RF transistor have substantially the same channel dimensions;
said receive shunt high breakdown voltage RF transistor and said receive shunt low breakdown voltage RF transistor have substantially the same channel dimensions.

12. The RF transceiver of claim 10, wherein said transmit shunt RF switch is situated between a power amplifier (PA) and a ground, and said receive shunt RF switch is situated between a low noise amplifier (LNA) and said ground.

13. The RF transceiver of claim 12, wherein said transmit input is coupled to said PA, and said receive output is coupled to said LNA.

14. The RF transceiver of claim 5, wherein said transmit series high breakdown voltage RF transistor and said transmit series low breakdown voltage RF transistor have substantially the same channel dimensions.

15. The RF transceiver of claim 5, wherein said receive series high breakdown voltage RF transistor and said receive series low breakdown voltage RF transistor have substantially the same channel dimensions.

16. The RF transceiver of claim 5, wherein:
said transmit series high breakdown voltage RF transistor and said transmit series low breakdown voltage RF transistor have substantially the same channel dimensions;
said receive series high breakdown voltage RF transistor and said receive series low breakdown voltage RF transistor have substantially the same channel dimensions.

17. The RF transceiver of claim 5, wherein:
said transmit series low breakdown voltage RF transistor and said receive series low breakdown voltage RF transistor have breakdown voltages of less than approximately three and a half volts (3.5 V);
said transmit series high breakdown voltage RF transistor and said receive series high breakdown voltage RF transistor have breakdown voltages of greater than approximately five volts (5 V).

18. The RF transceiver of claim 10, wherein:
said transmit shunt low breakdown voltage RF transistor and said receive shunt low breakdown voltage RF transistor have breakdown voltages of less than approximately three and a half volts (3.5 V);
said transmit shunt high breakdown voltage RF transistor and said receive shunt high breakdown voltage RF transistor have breakdown voltages of greater than approximately five volts (5 V).

19. The RF transceiver of claim 5, wherein:
each of said cascaded RF transistors of said transmit series stack has approximately the same breakdown voltage as either said transmit series high breakdown voltage RF transistor or said transmit series low breakdown voltage RF transistor;
each of said cascaded RF transistors of said receive series stack has approximately the same breakdown voltage as either said receive series high breakdown voltage RF transistor or said receive series low breakdown voltage RF transistor.

20. The RF transceiver of claim 10, wherein:
each of said cascaded RF transistors of said transmit shunt stack has approximately the same breakdown voltage as either said transmit shunt high breakdown voltage RF transistor or said transmit shunt low breakdown voltage RF transistor;
each of said cascaded RF transistors of said receive shunt stack has approximately the same breakdown voltage as either said receive shunt high breakdown voltage RF transistor or said receive shunt low breakdown voltage RF transistor.
